(19) United States
(12) Patent Application Publication
(10) Pub. No.: US 2008/0067509 A1
(43) Pub. Date: Mar. 20, 2008

(54) Chip Comprising at Least One Test Contact Configuration

(75) Inventors: Heimo Scheucher, Langegg (AT); Werner Puntigam, Edelschrott (AT); Thomas Burger, Graz (AT)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/574,239

(22) PCT Filed: Aug. 24, 2005
(86) PCT No.: PCT/IB05/52770

§ 371 Date: Oct. 8, 2007

(30) Foreign Application Priority Data
Aug. 31, 2004 (EP) 04104169.0

(51) Int. Cl. H01L 23/58

(52) U.S. Cl. 257/48; 257/E23.001

(57) ABSTRACT

In a chip (2) comprising a semiconductor body (6) and an integrated circuit (7) formed in the semiconductor body (6) and a passivation layer (14) designed to protect the integrated circuit (7) and a test contact configuration (15), the test contact configuration (15) has a test contact layer (16) lying below the passivation layer (14) and a test contact block (18) connected to the test contact layer (16), which test contact block (18) with a portion thereof projects through a hole (17) in the passivation layer (14) to the test contact layer (16) and is connected to the test contact layer (16), wherein the test contact block (18) has a contact region (20) lying above the passivation layer (14).

### FIELD OF THE INVENTION

The invention relates to a chip comprising a semiconductor body and an integrated circuit formed in the semiconductor body and a passivation layer designed to protect the integrated circuit and applied to the semiconductor body and a test contact layer lying below the passivation layer and a hole in the passivation layer, which hole is provided above the test contact layer and is designed to allow the establishment of an electrically conductive connection between the test contact layer and a test contact of a test device.

The invention furthermore relates to a wafer comprising a large number of chips of the type mentioned in the preceding paragraph.

### BACKGROUND OF THE INVENTION

A chip of the type mentioned in the first paragraph is known from the patent document DE 101 59 797 A1. In the known chip, the test contact layer is formed by a printed line portion of the integrated circuit, which printed line portion lies in the penultimate metal layer of the integrated circuit in relation to the passivation layer, wherein a pit-like recess is provided above this test contact layer, which recess extends from the test contact layer to the hole in the passivation layer which is provided above the test contact layer. A test needle designed as a test contact of a test device can be inserted through the hole in the passivation layer into said recess and can be moved toward the test contact layer, whereupon the test needle is in electrically conductive connection with the test contact layer. Once the test needle has been brought into electrically conductive connection with the test contact layer, a test operation can be carried out by means of the test device.

In the known chip, the cross-sectional dimensions of the hole in the passivation layer and the cross-sectional dimensions of the recess between the hole and the test contact layer and the cross-sectional dimensions of the test contact layer must be selected to be large enough for it to be possible for the test needle to be brought into electrically conductive connection with the test contact layer. Although it is desired to make such test needles increasingly thin, this desire is limited by the fact that such test needles are also exposed to mechanical stress when a test operation is carried out, which mechanical stress does not allow the cross-sectional dimensions of test needles to be reduced to below a certain limit. At present, test needles, which have a preferably circular cross section having a diameter of approximately 75 μm, and consequently a cross-sectional surface of approximately 4420 μm² are known and often used. If a test operation is to be carried out on the chip known from the patent document DE 101 59 797 A1 using such a test needle having a diameter of approximately 75 μm and consequently a cross-sectional surface of approximately 4420 μm², then a hole and a recess and a test contact layer which each have a cross-section which is considerably greater than the diameter of the test needle have to be provided in the known chip, as can be seen from the drawings of patent document DE 101 59 797 A1. This means that in the known chip a relatively large amount of chip surface is required for the means necessary for test purposes, namely the hole and the recess and the test contact layer, and this is disadvantageous with regard to saving as much chip surface as possible.

### OBJECT AND SUMMARY OF THE INVENTION

It is an object of the invention to overcome the abovementioned difficulties and to provide an improved chip and an improved wafer.

In order to achieve the above-described object, a chip according to the invention is provided with features according to the invention so that a chip according to the invention can be characterized as follows, namely:

A chip comprising a semiconductor body and an integrated circuit formed in the semiconductor body and a passivation layer designed to protect the integrated circuit and applied to the semiconductor body and a test contact layer lying below the passivation layer and a hole in the passivation layer, which hole is provided above the test contact layer and is designed to allow the establishment of an electrically conductive connection between the test contact layer and a test contact of a test device, wherein a test contact block is connected to the test contact layer, which test contact block covers the test contact layer and projects through the hole in the passivation layer and has a contact region designed to make contact with the test contact of the test device, which contact region lies above the passivation layer, and which test contact block has a cross-sectional surface running parallel to the region of the passivation layer which adjoins the test contact block, which cross-sectional surface has an area of at most 1600 μm².

In order to achieve the above-described object, a wafer according to the invention is provided with a large number of chips according to the invention.

By providing the features according to the invention, it is achieved in a structurally simple manner that, in a chip according to the invention, the test contact configuration of this chip which is necessary for test purpose, which test contact configuration comprises the test contact block and the test contact layer lying therebelow, is designed to be considerably smaller with regard to the required cross-sectional surface compared to the previously known solutions, whereby the significant advantage is obtained that the test contact configuration of a chip according to the invention which is necessary for test purposes takes up much less chip surface than in the known solutions. The test contact layer may be made of various materials, such as gold, silver, copper or other highly electrically conductive materials known in semiconductor technology. The test contact block may also be made of various materials, such as silver, copper, tin or other highly electrically conductive materials known in semiconductor technology.

The test contact layer and the test contact block may have been produced using various manufacturing methods and according to a number of variant embodiments. By way of example, the test contact layer and the test contact block may have a circular or hexagonal or octagonal cross-sectional surface or an L-shaped cross-sectional surface. In a chip, according to the invention, the test contact layer may also be formed by a so-called pad made of aluminum, and the test contact block may also be formed by a so-called bump made of gold, wherein the pad and the bump then preferably have a rectangular or square cross-sectional surface, which cross-sectional surface has side lengths of at most 40 μm. It should be mentioned at this point that, in respect of chips per se, it has been known for a long time to produce chip terminals using pads made of aluminum and bumps made of gold which are applied to the pads, although significantly larger cross-sectional surfaces are provided in the case of the chip terminals known to date which consist of pads and bumps, namely because these known chip terminals are in each case provided and designed to produce a connection to a so-called package contact. This production of a connection to such a package contact takes place either by means of bond technology, wherein bond wires have to be connected to the chip terminals and also have to be connected to the package contacts, or by means of a flip-chip technology, wherein the chip with its chip terminals has to be pressed against the package contacts. In each of the two technologies, there is the requirement that the chip terminals must be able to withstand, undamaged, relatively high stresses which are brought about as each of the two technologies is carried out on the chip terminals, and this necessarily means that chip terminals always have to have relatively large cross-sectional dimensions. Although this has been the case for many years and is known in technical circles, to date no-one has come up with the measures according to the invention, namely to design test contact configurations of a chip, which are required and used only for test purposes and consequently have to withstand only relatively low stresses, basically in the same way as conventional chip terminals, but to make these test contact configurations so small in terms of their effective cross section that a high saving in terms of chip surface is achieved. In the solution according to the invention, reliable production of an electrically conductive contact connection between a test contact of a test device and a test contact configuration of a chip is also ensured because, on account of the small size of the effective cross section of the test contact block of the test contact configuration, the test contact of the test device almost always reliably comes into contact with the effective cross section of the test contact block of the test contact configuration.

As already mentioned, the cross-sectional surface of the test contact block may have a circular shape or even be designed in an L-shaped manner. In a chip according to the invention, however, it has proven to be advantageous if the cross-sectional surface has a rectangular shape and is delimited by sides having at least one side length, wherein the at least one side length has a value of between 10 μm and 40 μm. This design is highly advantageous with regard to a solution, which can be produced in as simple a manner as possible and is as structurally simple as possible, as confirmed by test experiments.

In a chip according to the invention, the at least one side length may have a value of 10 μm, 15 μm, 20 μm, 25 μm, 35 μm or 40 μm. It has proven to be very advantageous if the at least one side length has a value of 30 μm. This is advantageous because in this design a good compromise is reached between a cross-sectional surface of a test contact configuration that is as small as possible on the one hand, and on the other hand a sufficiently high mechanical stability of the test contact configuration.

In a chip according to the invention, the cross-sectional surface of the test contact block may be rectangular. However, it has proven to be very advantageous if the cross-sectional surface of the test contact block is square. In this way, a particularly small cross-sectional size of the test contact block of a test contact configuration is achieved.

The abovementioned aspects and further aspects of the invention emerge from the example of embodiment described below and are explained with reference to this example of embodiment.

### BRIEF DESCRIPTION OF THE DRAWINGS

The invention will be further described with reference to an example of embodiment shown in the drawings to which, however, the invention is not restricted.

FIG. 1 schematically shows in plan view a wafer comprising chips and comprising longitudinal separation zones between the chips.

FIG. 2 shows, on a much larger scale than FIG. 1, part of a chip according to one example of embodiment of the invention.

### DESCRIPTION OF EMBODIMENTS

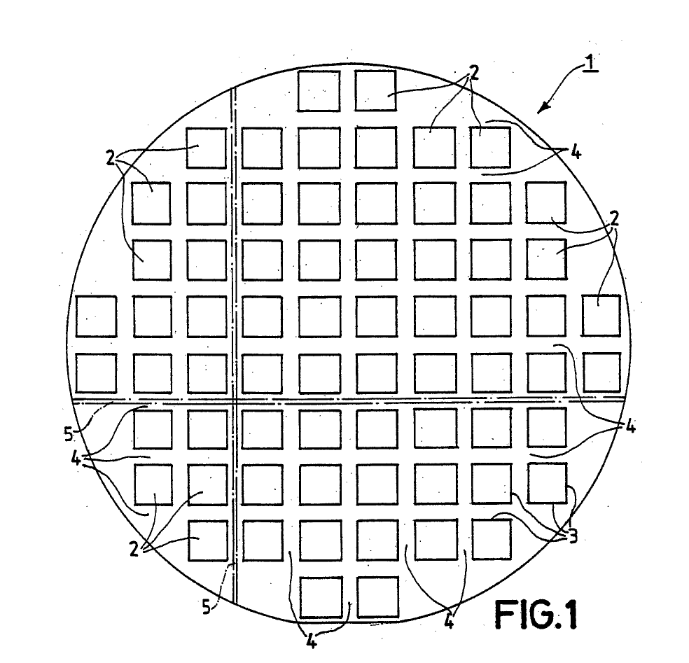

FIG. 1 shows a wafer 1 which comprises a large number of chips 2. The chips 2 are shown only schematically and without any greater detail in FIG. 1. Each chip 2 has a given chip surface, which chip surface lies within chip boundaries 3. In the case shown, the chip surface of each chip 2 is square, so that the chip boundaries 3 are of equal length. Rectangular chip surfaces are also known and possible. In a known manner, the chip surfaces and the chip boundaries 3 of each chip 2 are defined by exposure fields, which, during manufacture of the chip, are produced by means of exposure masks.

Narrow longitudinal separation zones 4 are provided between the chips 2. The separation zones 4 are provided for cutting through the wafer 1 for the purpose of separating the individual chips 2. In the present case, the wafer 1 is cut along cutting lines 5, of which cutting lines only two cutting lines 5 are shown in FIG. 1 by means of dash-dotted lines. The wafer 1 can be cut along the cutting lines 5, wherein special cutting blades are used for the cutting operation. Instead of cutting blades, however, it is also possible to use a laser cutting device or other cutting devices. The cutting may also be carried out by means of an etching process.

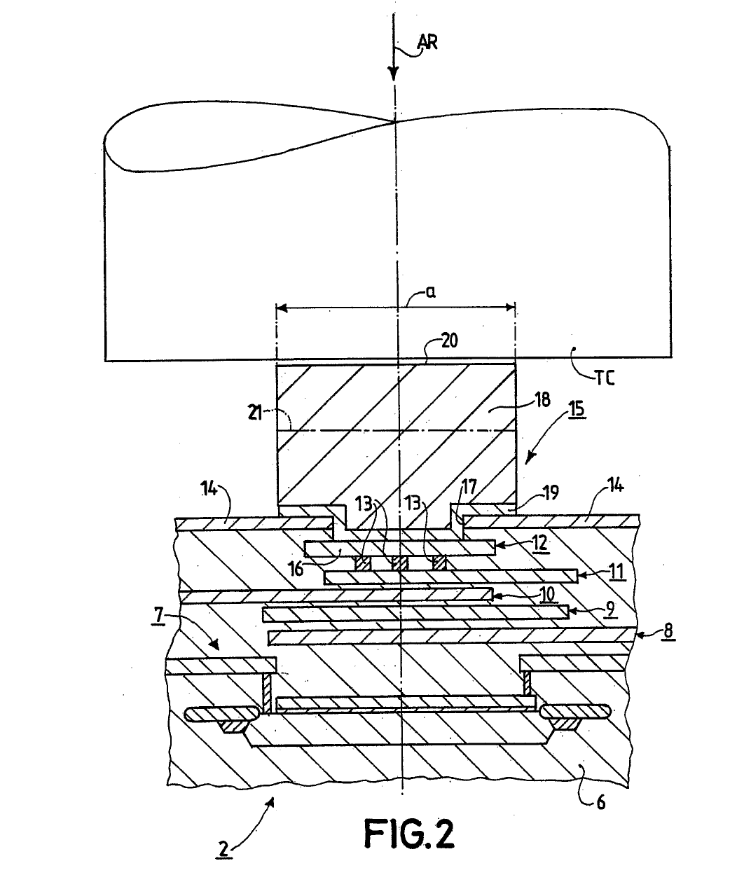

FIG. 2 shows only a very small part of a chip 2, which chip 2 has been produced by cutting out of the wafer 1 shown in FIG. 1. The chip 2 has a semiconductor body 6. An integrated circuit 7 is formed in the semiconductor body 6, only a very small part of said integrated circuit 7 being shown in FIG. 2. Five metal layers 8, 9, 10, 11, 12 are provided above the integrated circuit 7, in a manner lying one above the other. The metal layers 8 to 12 are in a known manner designed for the electrically conductive connection of circuit parts of the integrated circuit 7. Bridges are present between the metal layers 8 to 12, of which bridges three bridges 13 are shown in FIG. 2, which three bridges 13 are provided between the fourth metal layer 11 and the fifth metal layer 12. In the present case, the metal layers 8 to 12 and the bridges 13 are made of aluminum.

In order to protect the integrated circuit 7 and the metal layers 8 to 12 lying level thereabove and the bridges 13, the chip 2 has a passivation layer 14 applied to the semiconductor body 6. In the present case, the passivation layer 14 consists of silicon nitride (SiN) and has a thickness of approximately 1.5 μm. However, such a protective layer 14 may also be designed as two layers, and then consists of a layer of a so-called PSG having a thickness of 500 nm and of a layer of a nitride having a thickness of approximately 1000 nm, said latter layer being applied to the layer of PSG, so that the result is an overall thickness of approximately 1.5 μm.

In the chip 2, means are provided which can be used to test the chip 2. The manner of testing a chip has been known per se for a long time, and for this reason no further details will be given here with regard to the necessary test device and the test operations which can be carried out using the test device, as this is not essential in the present context. For test purposes, the chip 2 has a number of test contact configurations. Of all the test contact configurations of the chip 2, one test contact configuration 15 is shown in FIG. 2.

The test contact configuration 15 has a test contact layer 16 lying below the passivation layer 14, which test contact layer 16 is formed by the fifth metal layer 12. The test contact layer 16 is connected, in an electrically conductive manner and in a way not shown in any greater detail in FIG. 2, to a circuit part of the integrated circuit 7, which is to be tested. A hole 17 is provided in the passivation layer 14 above the test contact layer 16. The hole 17 is designed to allow the establishment of an electrically conductive connection between the test contact layer 16 and a test contact TC of a test device not shown in FIG. 2. The test contact TC is formed by a known test needle and can be placed onto the test contact configuration 15 in the direction of an arrow AR. In this case, the hole 17 has a square cross section, wherein the cross-sectional surface is 16 μm×16 μm.

In the chip 2, a test contact block 18 is connected to the test contact layer 16. For good and stable mechanical and electrical connection of the test contact block 18 to the test contact layer 16, a connecting layer 19 is provided which is to be regarded as part of the test contact block 18 and is made of titanium-tungsten (TiW) and has a thickness of approximately 1.0 μm. It may however also have a thickness of 1.5 μm or 2.0 μm. The test contact block 18 covers the test contact layer 16 and projects, with the connecting layer 19 to be assigned to the test contact block 18, through the hole 17 in the passivation layer 14. The test contact block 18 has a contact region 20 designed to make contact with the test contact TC of the test device, which contact region 20 lies above the passivation layer 14. The test contact block 18 is made of gold (Au), wherein the height of the test contact block 18 is selected such that its contact region 20 designed to cooperate with the test contact TC lies at a distance of approximately 18 μm from the passivation layer 14. The aforementioned distance between the contact region 20 and the passivation layer 14 may however also be only 15 μm or else 20 μm or 25 μm.

The test contact block 18 has a rectangular cross-sectional surface 21 which runs parallel to the region of the passivation layer 14 adjoining the test contact block 18, which cross-sectional surface 21 is shown schematically in FIG. 2 by a dash-dotted line. The cross-sectional surface 21 is delimited by four sides. In the present case, the cross-sectional surface 21 is delimited by four sides of equal length, wherein each of the four sides of equal length has a side length a. In the present case, the cross-sectional surface 21 of the test contact block 18 is square, wherein the side length a has a value of 30 μm. The side length a having a value of 30 μm is thus considerably smaller than the diameter of the test contact TC formed by a test needle, which diameter is approximately 75 μm. In the present embodiment of the test contact configuration 15, the cross-sectional surface 21 of the test contact block 18 has an area of less than 1600 μm², specifically only about 900 μm², and this is an essential prerequisite for achieving the advantages according to the invention. However, the test contact block 18 may also have a cross-sectional surface 21 with a rectangular shape, wherein the rectangular shape is delimited by two pairs of sides of different length having, a side length a and a side length b, wherein the side length a may have a value of 30 μm and the side length b may have a value of 40 μm. It is clear that the cross-sectional surface 21, may also be delimited by sides having other side lengths; by way of example, the side lengths may have a value of 10 μm, 15 μm, 20 μm, 25 μm, 35 μm and 40 μm. In any case, however, the side lengths of 40 μm and the cross-sectional surface of 1600 μm² represent the upper limits because only then is the advantage of sufficiently small test contact configurations 15 and consequently the advantage of a high saving in terms of chip surface ensured.

1. A chip comprising a semiconductor body and an integrated circuit formed in the semiconductor body and a passivation layer designed to protect the integrated circuit and applied to the semiconductor body and a test contact layer lying below the passivation layer and a hole in the passivation layer which hole is provided above the test contact layer and is designed to allow the establishment of an electrically conductive connection between the test contact layer and a test contact of a test device, wherein a test contact block is connected to the test contact layer which test contact block covers the test contact layer and protects through the hole in the passivation layer and has a contact region designed to make contact with the test contact of the test device, which contact region lies above the passivation layer and which test contact block has a cross-sectional surface running parallel to the region of the passivation layer which adjoins the test Contact block which cross-sectional surface has an area of at most 1660 μm².

2. A chip as claimed in claim 1, wherein the cross-sectional surface has a rectangular shape and is delimited by sides having at least one side length wherein the at least one side length has a value of between 10 μm and 40 μm.

3. A chip as claimed in claim 2, wherein the at least one side length has a value of 30 μm.

4. A chip as claimed in claim 2, wherein the cross-sectional surface of the test contact block has a square shape.

5. A wafer comprising a large number of chips wherein the wafer comprises a large number of chips as claimed in claim 1.
